(19) United States
(12) Patent Application Publication
(10) Pub. No.: US 2021/0119176 A1
(43) Pub. Date: Apr. 22, 2021

(54) OLED ENCAPSULATION METHOD AND OLED ENCAPSULATION STRUCTURE

(71) Applicant: Shenzhen China Star Optoelectronics Technology Co., Ltd., Shenzhen (CN)

(72) Inventor: Hui Huang, Shenzhen (CN)

(21) Appl. No.: 16/307,138

(22) PCT Filed: Sep. 18, 2018
(86) PCT No.: PCT/CN2018/106336

§ 371 Date: Dec. 5, 2018

(30) Foreign Application Priority Data
May 16, 2018 (CN) 201810469332.2

(51) Int. Cl. H01L 51/52; H01L 51/56

(52) U.S. Cl. CPC H01L 51/5253; H01L 51/56

(57) ABSTRACT

The invention provides an OLED encapsulation method and an OLED encapsulation structure. The OLED encapsulation method obtains a plurality of grooves by patterning a barrier layer formed on the OLED device, forms a surface active layer in the plurality of grooves, and then forms a buffer layer. Because of the effect of the surface active layer, the material diffusion speed is accelerated, the leveling is more favorable, and the film thickness uniformity of the buffer layer is improved.

### BACKGROUND OF THE INVENTION

### 1. Field of the Invention

The present invention relates to the field of display, and in particular to an organic light-emitting diode (OLED) encapsulation method and OLED encapsulation structure.

### 2. The Related Arts

The organic light-emitting diode (OLED) display device, also known as an organic electroluminescent display, is an emerging panel display device. The OLED display device provides the advantages of self-luminous, low driving voltage, high luminous efficiency, short response time, high definition and contrast, near 180° viewing angle, wide temperature range, and ability to realize flexible display and larges-size full-color display, and so on, and are recognized by the industry as the most promising display device.

The OLED device generally comprises a substrate, an anode disposed on the substrate, a hole injection layer disposed on the anode, a hole transport layer disposed on the hole injection layer, a light-emitting layer disposed on the hole transport layer, an electron transport layer disposed on the light-emitting layer, an electron injection layer disposed on the electron transport layer, and a cathode disposed on the electron injection layer. The light emission principle of OLED devices is that semiconductor materials and organic materials and light-emitting materials are driven by electric fields, causing carrier injection and recombination to emit light. Specifically, an OLED device generally uses an indium tin oxide (ITO) electrode and a metal electrode as anodes and cathodes of the device, respectively. Under a certain voltage, electrons and holes are injected from the cathode and the anode into the electron injection layer and the hole injection layer, respectively. The electrons and holes migrate to the light-emitting layer through the electron transport layer and the hole transport layer, respectively, and meet in the light-emitting layer to form excitons and excite the light-emitting molecules, and the latter emits visible light through radiation relaxation.

In the existing OLED film encapsulation, the encapsulation layer is generally prepared by vacuum deposition or inkjet printing to prepare a barrier layer and a buffer layer, and the encapsulation effect is achieved by superposition of several layers. To obtain a better buffering effect, inkjet printing is usually used. However, because a gap exists between the inkjet printing heads, the buffer layer after inkjet printing is generally completely flattened to device by static leveling to achieve the purpose of covering and encapsulation. Therefore, the encapsulation time is prolonged, and the thickness uniformity of the buffer layer film is difficult to ensure.

### SUMMARY OF THE INVENTION

The object of the present invention is to provide an OLED encapsulation method, forming surface active layer on a plurality of grooves in the barrier layer to accelerate the material diffusion of the buffer layer, favorable to the leveling, and improving film thickness uniformity of the buffer layer.

Another object of the present invention is to provide an OLED encapsulation structure, having surface active layer formed on a plurality of grooves in the barrier layer and improving film thickness uniformity of the buffer layer.

To achieve the above object, the present invention provides an OLED encapsulation method, which comprises:

Step S1: providing a substrate, forming an OLED device on the substrate;

Step S2: forming a barrier layer on the substrate to cover the OLED device, patterning the barrier layer to form a plurality of grooves on the barrier layer;

Step S3: forming a surface active layer on each of the plurality of grooves;

Step S4: forming a buffer layer on the barrier layer and the surface active layer.

Wherein, the OLED device comprises a plurality of sub-pixel areas arranged in an array, and the plurality of grooves are disposed corresponding to the plurality of sub-pixel areas.

Wherein, the area of the groove is greater than or equal to the area of the sub-pixel area.

Wherein, the thickness of the surface active layer is equal to the depth of the groove.

Wherein, in step S3, a surface active layer is formed by coating, spraying or inkjet printing a surfactant in the plurality of grooves.

Wherein, the surfactant is a hydrophilic polymer active material containing a hydroxyl group or a hydrogen ion.

The present invention also provides an OLED encapsulation structure, which comprises: a substrate, an OLED device disposed on the substrate, and a thin film encapsulation layer disposed on the substrate and covering the OLED device;

the thin film encapsulation layer comprising: at least a barrier layer and at least a buffer layer, alternately stacked, and a surface active layer disposed between the barrier layer and the buffer layer and located in a plurality of grooves on the barrier layer.

Wherein, the OLED device comprises a plurality of sub-pixel areas arranged in an array, and the plurality of grooves are disposed corresponding to the plurality of sub-pixel areas.

Wherein, the area of the groove is greater than or equal to the area of the sub-pixel area.

Wherein, the thickness of the surface active layer is equal to the depth of the groove.

The present invention provides the following advantages: in the OLED encapsulation method of the present invention, a plurality of grooves are obtained by patterning a barrier layer formed on an OLED device, a surface active layer is formed in the plurality of grooves, and then a buffer layer is formed. The surface active layer accelerates the material diffusion for the buffer layer, is more conducive to leveling, and improves the film thickness uniformity of the buffer layer. In the OLED encapsulation structure of the present invention, a surface active layer is disposed in a plurality of grooves on the barrier layer in the thin film encapsulation layer, and the material diffusion speed of the buffer layer is accelerated due to the effect of surface active layer, the leveling is more favorable, and the film thickness uniformity of the buffer layer is improved.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the flowchart of the OLED encapsulation method of the present invention;

FIG. 2 is a schematic view showing step S1 of the OLED encapsulation method of the present invention;

FIG. 3 is a schematic view showing step S2 of the OLED encapsulation method of the present invention;

FIG. 4 is a schematic view showing step S3 of the OLED encapsulation method of the present invention;

FIG. 5 is a schematic view showing step S4 of the OLED encapsulation method and the OLED encapsulation structure of the present invention;

FIG. 6 is a top view showing the barrier layer of the OLED encapsulation structure of the present invention.

### DETAILED DESCRIPTION OF THE PREFERRED EMBODIMENTS

To further explain the technical means and effect of the present invention, the following refers to embodiments and drawings for detailed description.

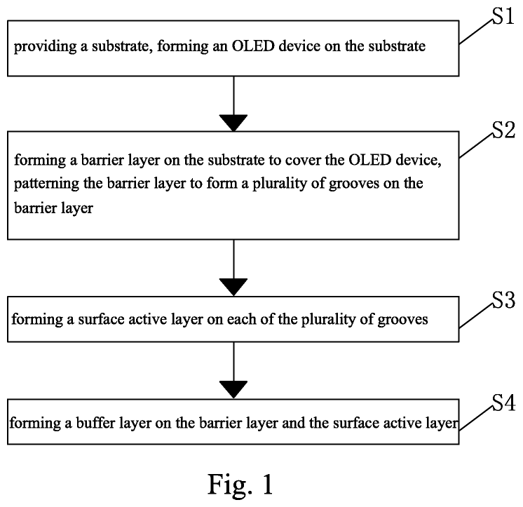

Refer to FIG. 1. The OLED encapsulation method of the present invention comprises the following steps:

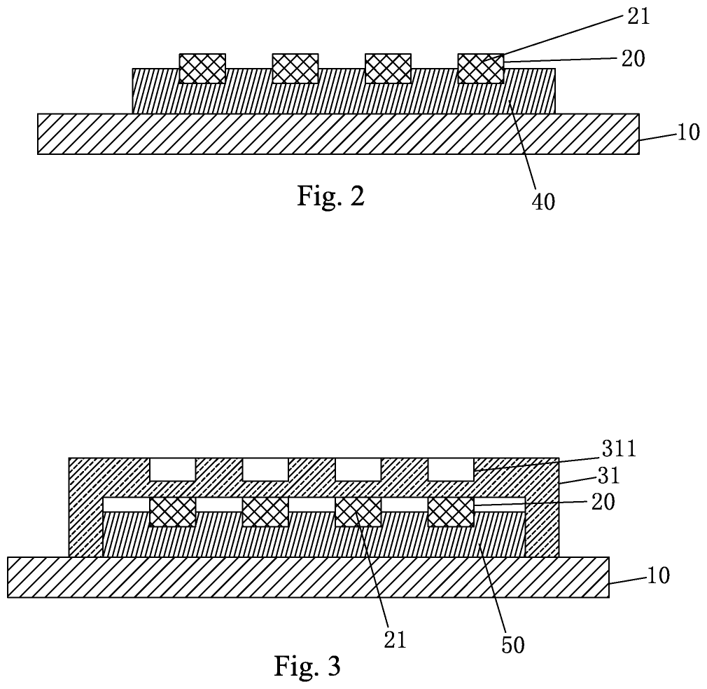

Step S1: as shown in FIG. 2, providing a substrate 10, forming an OLED device 20 on the substrate 10;

Step S2: as shown in FIG. 3, forming a barrier layer 31 on the substrate 10 to cover the OLED device 20, patterning the barrier layer 31 to form a plurality of grooves 311 on the barrier layer 31;

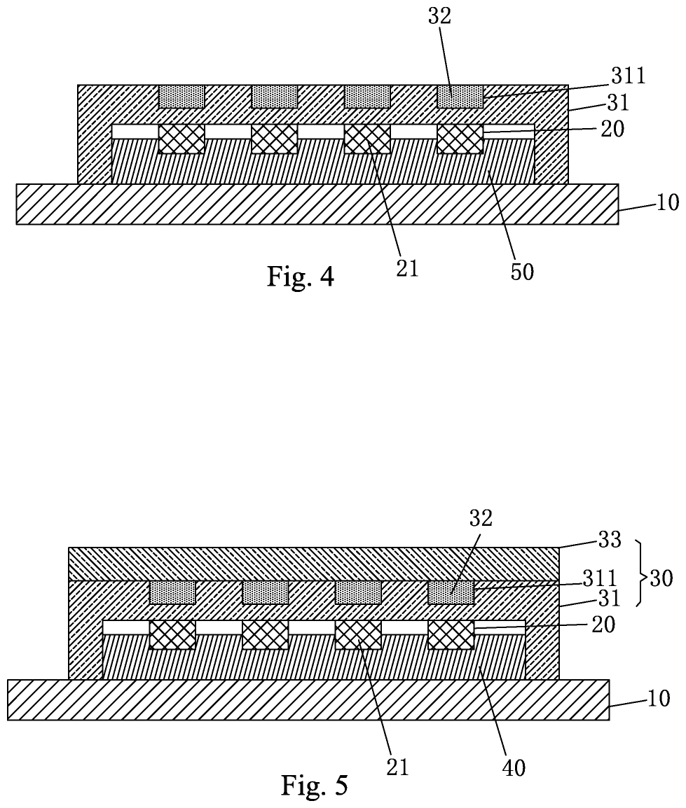

Step S3: as shown in FIG. 4, forming a surface active layer 32 on each of the plurality of grooves 311;

Step S4: as shown in FIG. 5, forming a buffer layer 33 on the barrier layer 31 and the surface active layer 32.

It should be noted that present invention patterns the barrier layer 31 formed on the OLED device 20 to obtain the plurality of grooves 311, forms the surface active layer 32 in the plurality of grooves 311, and then forms a buffer layer 33. The surface active layer 32 accelerates the material diffusion for the buffer layer 33, is more conducive to leveling, and improves the film thickness uniformity of the buffer layer 33.

Specifically, the OLED encapsulation method further comprises a step S5, i.e., repeating steps S2-S4, forming a structure wherein the multi-layer barrier layer 31 and the multi-layer buffer layer 33 are alternately stacked on the OLED device 20, thereby improving the ability to block water and oxygen.

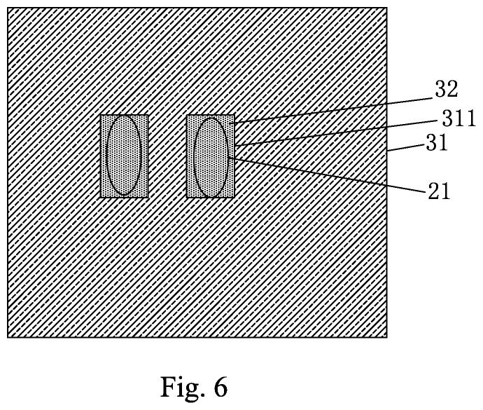

Specifically, referring to FIG. 6, the OLED device 20 comprises a plurality of sub-pixel areas 21 arranged in an array, and the plurality of grooves 311 are disposed corresponding to the plurality of sub-pixel areas 21. As such, the surface active layer 32 covers the plurality of sub-pixel areas 21, so that the film thickness uniformity of the buffer layers 33 on the plurality of sub-pixel areas 21 is consistent, to improve the light uniformity of the OLED device 20.

Moreover, the area of the groove 311 is greater than or equal to the area of the sub-pixel area 21, which is favorable for the surface active layer 31 to fully cover the plurality of sub-pixel areas 21.

Specifically, in step S2, the formation of the barrier layer 31 covering the OLED device 20 is formed on the substrate 10 by chemical vapor deposition.

Specifically, in step S3, the surface active layer 32 is formed by coating, spraying or inkjet printing a surfactant in the plurality of grooves 311.

Moreover, the surfactant is a hydrophilic polymer active material containing a hydroxyl group or a hydrogen ion (H+). Preferably, the material is a polyol or an ether material (such as, sodium sodium dodecyl benzene sulfonate (SDBS) or a homologous material), which forms a hydrogen bond with a hydroxyl group and a hydrogen ion (H+) in the buffer layer 33 to enhance the bonding ability and improve the encapsulation effect.

Preferably, the thickness of the surface active layer 33 is equal to the depth of the groove 311, which is favorable for the material diffusion of the buffer layer 33 to ensure the thickness uniformity of the buffer layer 33.

Specifically, in step S4, a buffer layer material is coated or ink-jet printed on the barrier layer 31 and the surface active layer 32, and the buffer layer 33 is formed after standing and leveling.

Specifically, step S1 further comprises a step of forming a thin film transistor (TFT) layer 40 between the substrate 10 and the OLED device 20.

Refer to FIG. 5. Based on the above OLED encapsulation method, the present invention also provides an OLED encapsulation structure, which comprises: a substrate 10, an OLED device 20 disposed on the substrate 10, and a thin film encapsulation layer 30 disposed on the substrate 10 and covering the OLED device 20.

The thin film encapsulation layer 30 comprises: at least a barrier layer 31 and at least a buffer layer 33, alternately stacked, and a surface active layer 32 disposed between the barrier layer 31 and the buffer layer 33 and located in a plurality of grooves 311 on the barrier layer 31.

It should be noted that in the OLED encapsulation structure of the present invention, the surface active layer 32 is disposed in a plurality of grooves 311 on the barrier layer 31 in the thin film encapsulation layer 30, and the material diffusion speed of the buffer layer 33 is accelerated due to the effect of surface active layer 32, the leveling is more favorable, and the film thickness uniformity of the buffer layer 33 is improved.

Specifically, referring to FIG. 6, the OLED device 20 comprises a plurality of sub-pixel areas 21 arranged in an array, and the plurality of grooves 311 are disposed corresponding to the plurality of sub-pixel areas 21. As such, the surface active layer 32 covers the plurality of sub-pixel areas 21, so that the film thickness uniformity of the buffer layers 33 on the plurality of sub-pixel areas 21 is consistent, to improve the light uniformity of the OLED device 20.

Moreover, the area of the groove 311 is greater than or equal to the area of the sub-pixel area 21, which is favorable for the surface active layer 31 to fully cover the plurality of sub-pixel areas 21.

Specifically, the formation of the barrier layer 31 covering the OLED device 20 is formed on the substrate 10 by chemical vapor deposition.

Specifically, the surface active layer 32 is formed by coating, spraying or inkjet printing a surfactant in the plurality of grooves 311.

Moreover, the surfactant is a hydrophilic polymer active material containing a hydroxyl group or a hydrogen ion (H+). Preferably, the material is a polyol or an ether material (such as, sodium sodium dodecyl benzene sulfonate (SDBS) or a homologous material), which forms a hydrogen bond with a hydroxyl group and a hydrogen ion (H+) in the buffer layer 33 to enhance the bonding ability and improve the encapsulation effect.

Preferably, the thickness of the surface active layer 33 is equal to the depth of the groove 311, which is favorable for the material diffusion of the buffer layer 33 to ensure the thickness uniformity of the buffer layer 33.

Specifically, a buffer layer material is coated or ink-jet printed on the barrier layer 31 and the surface active layer 32, and the buffer layer 33 is formed after standing and leveling.

Specifically, the OLED encapsulation structure further comprises a step of forming a thin film transistor (TFT) layer 40 between the substrate 10 and the OLED device 20.

In summary, in the OLED encapsulation method of the present invention, a plurality of grooves are obtained by patterning a barrier layer formed on an OLED device, a surface active layer is formed in the plurality of grooves, and then a buffer layer is formed. The surface active layer accelerates the material diffusion for the buffer layer, is more conducive to leveling, and improves the film thickness uniformity of the buffer layer. In the OLED encapsulation structure of the present invention, a surface active layer is disposed in a plurality of grooves on the barrier layer in the thin film encapsulation layer, and the material diffusion speed of the buffer layer is accelerated due to the effect of surface active layer, the leveling is more favorable, and the film thickness uniformity of the buffer layer is improved.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) encapsulation method, comprising:
Step S1: providing a substrate, forming an OLED device on the substrate;
Step S2: forming a barrier layer on the substrate to cover the OLED device, patterning the barrier layer to form a plurality of grooves on the barrier layer;
Step S3: forming a surface active layer on each of the plurality of grooves;
Step S4: forming a buffer layer on the barrier layer and the surface active layer.

2. The OLED encapsulation method as claimed in claim 1, wherein the OLED device comprises a plurality of sub-pixel areas arranged in an array, and the plurality of grooves are disposed corresponding to the plurality of sub-pixel areas.

3. The OLED encapsulation method as claimed in claim 2, wherein the area of the groove is greater than or equal to the area of the sub-pixel area.

4. The OLED encapsulation method as claimed in claim 1, wherein the thickness of the surface active layer is equal to the depth of the groove.

5. The OLED encapsulation method as claimed in claim 1, wherein in step S3, a surface active layer is formed by coating, spraying or inkjet printing a surfactant in the plurality of grooves.

6. The OLED encapsulation method as claimed in claim 5, wherein the surfactant is a hydrophilic polymer active material containing a hydroxyl group or a hydrogen ion.

7. An organic light-emitting diode (OLED) encapsulation structure, comprising: a substrate, an OLED device disposed on the substrate, and a thin film encapsulation layer disposed on the substrate and covering the OLED device;
the thin film encapsulation layer comprising: at least a barrier layer and at least a buffer layer, alternately stacked, and a surface active layer disposed between the barrier layer and the buffer layer and located in a plurality of grooves on the barrier layer.

8. The OLED encapsulation structure as claimed in claim 7, wherein the OLED device comprises a plurality of sub-pixel areas arranged in an array, and the plurality of grooves are disposed corresponding to the plurality of sub-pixel areas.

9. The OLED encapsulation structure as claimed in claim 8, wherein the area of the groove is greater than or equal to the area of the sub-pixel area.

10. The OLED encapsulation structure as claimed in claim 7, wherein the thickness of the surface active layer is equal to the depth of the groove.
